(19) United States
(12) Patent Application Publication
(10) Pub. No.: US 2014/0167995 A1
(43) Pub. Date: Jun. 19, 2014

(54) ANALOG-TO-DIGITAL CONVERTER

(71) Applicants: Kei Tee Tiew, Singapore (SG); Kok Lim Chan, Singapore (SG); Minkyu Je, Singapore (SG); Xiaojun Yuan, Singapore (SG)

(72) Inventors: Kei Tee Tiew, Singapore (SG); Kok Lim Chan, Singapore (SG); Minkyu Je, Singapore (SG); Xiaojun Yuan, Singapore (SG)

(73) Assignee: AGENCY FOR SCIENCE, TECHNOLOGY AND RESEARCH, Singapore (SG)

(21) Appl. No.: 14/111,016

(22) PCT Filed: Apr. 11, 2012
(86) PCT No.: PCT/SG2012/000128

§ 371 Date: Jan. 21, 2014

(30) Foreign Application Priority Data
Apr. 11, 2011 (SG) 201102570-7

(51) Int. Cl. H03M 1/00; H03M 3/00

(52) U.S. Cl. CPC H03M 1/002; H03M 3/30
USPC 341/143

(57) ABSTRACT

According to embodiments of the present invention, an analog-to-digital converter is provided. The analog-to-digital converter includes an input configured to receive an input signal, a feed-forward path connected to the input configured to feed forward the input signal, a processing path including a loop filter, wherein the loop filter includes at least one local feedback path configured to feed back an output signal of the loop filter to an input of the loop filter, a first combiner configured to combine the input signal fed forward by the feed-forward path with an output of the processing path, a quantizer configured to generate an output signal of the converter, a feed-back path configured to feed back the output signal, and a second combiner wherein the processing path is connected to the second combiner and the second combiner is configured to combine the input signal with the fed back output signal of the converter and supply the result of the combination to the processing path.

### CROSS-REFERENCE TO RELATED APPLICATION

This application claims the benefit of priority of Singapore patent application No. 201102570-7, filed 11 Apr. 2011, the content of it being hereby incorporated by reference in its entirety for all purposes.

### TECHNICAL FIELD

Various embodiments relate to an analog-to-digital converter.

### BACKGROUND

Many applications such as integrated MEMS SoCs require small analog-to-digital converter (ADC) footprint, e.g. tactile sensor and digital microphone. Successive approximation analog-to-digital converter (SAR ADC) is power efficient but occupies a larger area with a resolution <10-bit. High-end accelerometer, gyroscope, hydrophone and etc. require high resolution ADC which can only be achieved with delta-sigma modulators (DSMs).

Delta-sigma analog-to-digital converters (ADCs) or modulators are used in high resolution and low to medium speed ADCs. More recently, some attempts have been made to extend the speed of delta-sigma ADCs. Another interesting application is in cognitive or software defined radio, in which a delta-sigma ADC can be used to support multi-standard applications by trading off resolution and bandwidth.

However, conventional DSMs have a limiting factor of area efficiency, where a conventional 2nd-order switched capacitor (SC) DSM requires 2 OTAs and capacitors occupying most of the die area. Conventional DSMs also have a power-resolution trade-off where a higher resolution necessitates a higher sampling frequency (f_{S}), where an operational transconductance amplifier (OTA) of the DSM has a gain-bandwidth product (GBW) of >5×f_{S}, thereby consuming large power.

FIG. 1 shows a schematic block diagram of a delta-sigma modulator or ADC 100, consisting of a delta-sigma modulator 102 and a decimation filter 104. The input is sampled at a sampling frequency (f_{S}) much higher than twice the signal bandwidth (2×f_{B}) by the modulator 102 and subsequently filtered and down-sampled to the Nyquist rate multi-bit output by the decimation filter 104.

The theoretical dynamic range (DR) achievable by a delta-sigma modulator may be given by Equation 1:

$$DR = \frac{3}{2} \times \frac{( 2 L + 1 ) {M}^{2 L + 1}}{{π}^{2 L}} \times {( {2}^{B} - 1 )}^{2} \qquad ( Equation 1 )$$

where L is the order of a delta-sigma modulator 102, M is the oversampling ratio (=f_{S}/2f_{B}) and B is the number of bits used in the quantizer of the modulator 102.

Based on Equation 1, increasing the DR for a given f_{B} requires either an increase in L, M or B. A higher L means a higher order loop filter, which translates to more complex circuit blocks and is more prone to instability. For a given f_{B}, increasing M means a higher f_{S}, which results in excessive power consumption or may be limited by process technology. Increasing B reduces the quantization error but introduces DAC nonlinearity in the feedback path due to DAC element mismatches, which have to be mitigated with either some dynamic element matching (DEM) algorithms or calibration schemes.

The challenge in delta-sigma modulator design is to choose the values for L, M and B and a suitable architecture for implementation to achieve a certain DR requirement for a given conversion bandwidth. Extensive behavioral simulations including the effects of non-idealities in circuit building blocks may then be performed to determine the final architectural choice and circuit block specifications, subject to constraints such as power consumption and silicon area.

FIG. 2 shows a schematic block diagram of a double sampling single amplifier second-order delta-sigma modulator 200 of the prior art. The modulator 200 employs a mismatch cancellation scheme.

The architecture of the modulator shown in FIG. 2 and the associated circuit implementation uses a single operational transconductance amplifier (OTA) to implement the loop filter H(z) 202, as opposed to that of conventional second-order delta-sigma modulator which employs two OTAs (see FIG. 3). The p-path 204 in the loop filter H(z) 202 is implemented by adding a local feedback path to a switched-capacitor (SC) integrator in the loop filter H(z) 202. The extra 1-cycle delay in the q-path 206 is realized by using an additional capacitor (not shown) to sample the output and feedback to the input after an additional 1-cycle delay, as represented by the “z⁻¹” block 208.

The p-path 204 and the q-path 206 are fed back to a summer 210 in series with another summer 212 in order to also receive the output of the summer 212 as one of the inputs for the summer 210, and then produces an output which is delayed by a unit cycle, as represented by the “z⁻¹” block 214. The signal as delayed after the “z⁻¹” block 214 are fed back to the p-path 204 and the q-path 206, as well as provided to a quantizer 216.

The output signal from the quantizer 216 is then fed back through a filter 218 having a filter transfer function, G(z)=2−z⁻¹. The outputs from the filter 218 are then fed to the summer 212, where the summer 212 also receives an input signal X(z).

The transfer function based on the linearized model for the modulator 200 may be given by:

$$Y ( z ) = \frac{H ( z )}{1 + G ( z ) H ( z )} X ( z ) + \frac{1}{1 + G ( z ) H ( z )} E ( z ) \qquad ( Equation 2 )$$

where Y(z), X(z) and E(z) represent the output, the input and the quantization error of the quantizer 216 respectively.

When p=2, q=1 and G(z)=2−z⁻¹, Equation 2 may be simplified to the familiar second-order delta-sigma modulator transfer function as shown in Equation 3 below:

Y(z)=z⁻¹X(z)+(1−z⁻¹)²E(z) (Equation 3)

which indicates that the output Y(z) consists of a delayed version of the input X(z) and a second-order noise-shaped quantization error E(z).

The modulator 200 makes use of double-sampling switched-capacitor (SC) circuits to effectively double the sampling frequency of the modulator 200 at a given clock frequency, thereby potentially improving the resolution of the modulator 200 by (L+0.5) bits according to Equation 1, as compared to conventional SC circuits in which the OTA only processes the input charge transfer in one of the two non-overlapping clock phases.

However, the modulator 200 as shown in FIG. 2 have some drawbacks as follows: (1) The feedback path contains a transfer function of G(z)=2−z⁻¹, which requires additional SC DAC sampling capacitors. For example, the modulator 200 requires 2 DACs (i.e. “DAC1”, “DAC2”) respectively in each of the two paths from the filter 218, thereby requiring 3 times more capacitor area compared to one DAC. These additional sampling capacitors and those in the p-path 204 and the q-path 206 in H(z) 202 increase the input-referred (referred to the input sampling capacitors) kT/C noise (k is the Boltzmann's constant; T is the absolute temperature; and C is the capacitance) and the feedback factor of an SC integrator. The former necessitates the use of larger sampling capacitors which increases power consumption while the latter increases the settling time of the SC integrator (i.e. slower settling speed of the loop filter H(z) 202); (2) The OTA must have sufficient open loop dc gain to minimize deviation in transfer function resulting in in-band quantization noise leakage which degrades the SNR. In addition, the OTA must have sufficient linearity as it processes both the input and quantization error; and (3) In order to limit the output signal range of the OTA, a multi-bit quantizer has to be used to reduce the quantization error, necessitating the use of more complicated dynamic element matching (DEM) algorithm or calibration scheme to mitigate the nonlinearity in the SC DAC due to mismatch in capacitors. For example, an individual level averaging (ILA) DEM scheme may be employed for a 5-level quantizer.

FIGS. 3A and 3B show schematic block diagrams respectively of a conventional second-order delta-sigma modulator architecture 300 and a feed-forward second-order delta-sigma modulator architecture 330 of the prior art.

The modulator 300 includes two integrators, denoted by H(z) blocks 302, 304, coupled with a summer 306 in between. Each of the H(z) blocks 302, 304 is implemented with an OTA, thereby requiring 2 OTAs in the modulator 300. The output of the integrator 304, yᵢ₂, is provided to a quantizer 308, where the output, v, from the quantizer 308 is then fed back to a digital-to-analog converter (D/A) 310, and then to the summer 306 to be summed with the output, yᵢ₁, from the integrator 302, and to another summer 312, which also receives an input signal, u, and provides an output, e, to the integrator 302.

The modulator 330 also includes two integrators, denoted by H(z) blocks 332, 334. Each of the H(z) blocks 332, 334 is implemented with an OTA, thereby requiring 2 OTAs in the modulator 330. The output, yᵢ₁, of the integrator 332 is fed to the integrator 334, as well as directly to a summer 336 which also receives the output, yᵢ₂, of the integrator 334. The output from the summer 336 is then passed to another summer 338 which is also fed with an input signal, u. The output from the summer 338 is then provided to a quantizer 340, producing an output, v, which is fed back to a digital-to-analog converter (D/A) 342, and then to a summer 344, which also receives the input signal, u, and provides an output, e, to the integrator 332.

The modulator 300 has two DAC feedback paths to the summers 306, 312, while the modulator 330 has one DAC feedback path to the summer 344 with an additional feed-forward path direct from the input to the summer 338. Therefore, the modulator 300 may have a higher input noise, a slower settling time, and a higher linearity requirement.

The integrators 302, 304, 332, 334 have a transfer function of

$$H ( z ) = \frac{{z}^{- 1}}{( 1 - {z}^{- 1} )} ,$$

such that the respective transfer functions of the modulator 300 and the modulator 330 may be given by Equations 4 and 5 below.

Y(z)=z⁻²X(z)+(1−z⁻¹)²E(z) (Equation 4),

Y(z)=X(z)+(1−z⁻¹)²E(z) (Equation 5).

where Y(z), X(z) and E(z) represent the output, the input and the quantization error of the quantizer 308, 340 respectively.

For the modulator 330, the integrator 332 sees an input of X(z)−Y(z)=(1−z⁻¹)² E(z), i.e. the integrator 332 only processes the noise-shaped quantization error instead of both the input and quantization error as in the modulator 300. Hence, the linearity of the OTA employed in H(z) could be relaxed and the output signal range may be determined by the magnitude of quantization error alone.

### SUMMARY

According to an embodiment, an analog-to-digital converter is provided. The analog-to-digital converter may include an input configured to receive an input signal, a feed-forward path connected to the input configured to feed forward the input signal, a processing path including a loop filter, wherein the loop filter includes at least one local feedback path configured to feed back an output signal of the loop filter to an input of the loop filter, a first combiner configured to combine the input signal fed forward by the feed-forward path with an output of the processing path, a quantizer configured to generate an output signal of the converter, a feed-back path configured to feed back the output signal, and a second combiner wherein the processing path is connected to the second combiner and the second combiner is configured to combine the input signal with the fed back output signal of the converter and supply the result of the combination to the processing path.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic block diagram of a delta-sigma modulator.

FIG. 2 shows a schematic block diagram of a double sampling single amplifier second-order delta-sigma modulator of the prior art.

FIGS. 3A and 3B show schematic block diagrams respectively of a conventional second-order delta-sigma modulator architecture and a feed-forward second-order delta-sigma modulator architecture of the prior art.

FIG. 4A shows a schematic block diagram of an analog-to-digital converter, according to various embodiments.

FIG. 4B shows a schematic block diagram of an analog-to-digital converter, according to various embodiments.

FIG. 5A shows a schematic block diagram of an analog-to-digital converter, according to various embodiments.

FIG. 5B shows a detailed schematic block diagram of the analog-to-digital converter of the embodiment of FIG. 5A.

FIG. 6 shows a schematic diagram of a circuit implementation of the loop filter, according to various embodiments.

FIG. 7 shows a schematic diagram of a circuit implementation of the first combiner and the quantizer, according to various embodiments.

FIG. 8 shows a schematic block diagram of an analog-to-digital converter incorporating two-path summer and analog-to-digital converters, according to various embodiments.

FIG. 9 shows a schematic diagram of a circuit implementation of a three-level switched capacitor (SC) digital-to-analog converter (DAC), according to various embodiments.

FIG. 10A shows a plot of simulated results of signal-to-noise and distortion ratio (SNDR) against input level for an oversampling ratio of 128, according to various embodiments.

FIG. 10B shows a plot of simulated results of loop filter outputs (Vmax and Vmin) against input level, according to various embodiments.

FIG. 11 shows a plot of output spectra for the analog-to-digital converter of various embodiments.

FIG. 12A shows a plot of measured results of signal-to-noise and distortion ratio (SNDR) against input level for different oversampling ratios, according to various embodiments.

FIG. 12B shows a plot of measured output spectra for the analog-to-digital converter of various embodiments for different input levels.

FIG. 13 shows a chip microphotograph of the analog-to-digital converter of various embodiments.

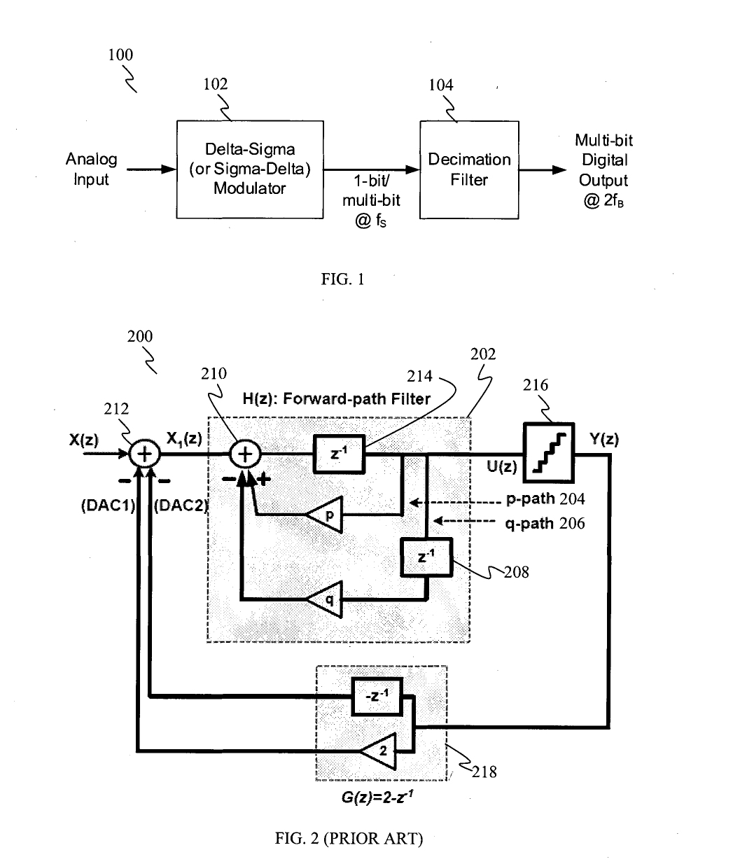

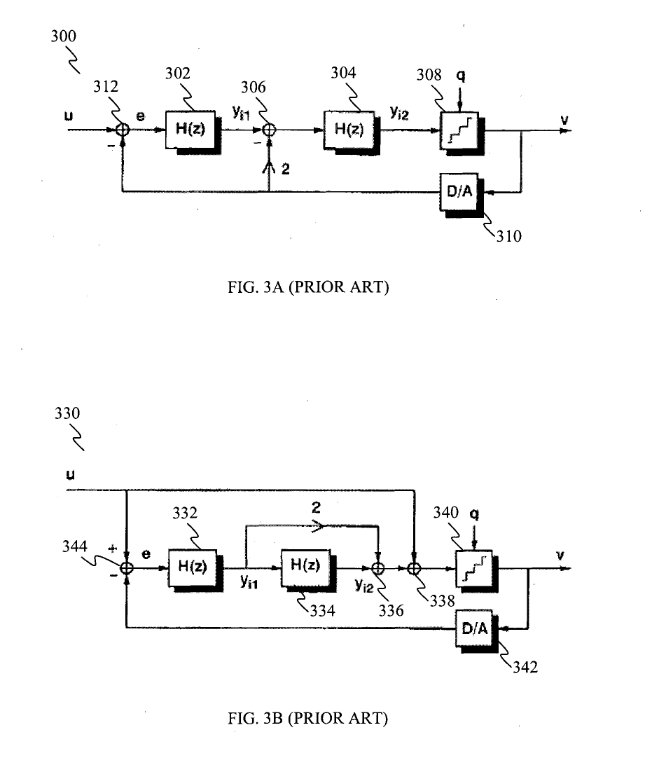

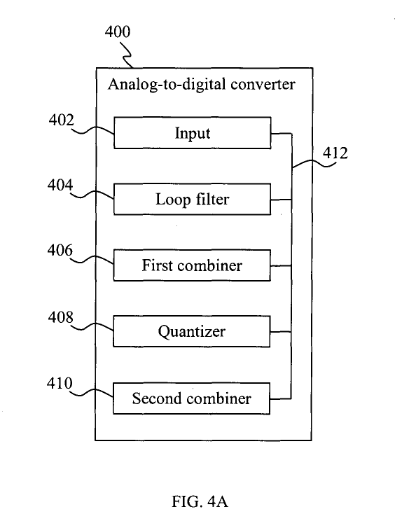

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other method or device. Similarly, embodiments described in the context of a method are analogously valid for a device, and vice versa.

In the context of various embodiments, the term “about” or “approximately” as applied to a numeric value encompasses the exact value and a variance of +/−5% of the value.

As used herein, the term “and/or” includes any and all combinations of one or more of the associated listed items.

Various embodiments relate to analog-to-digital converters (ADCs), for example delta-sigma, ΔΣ, (or sigma-delta, ΣΔ) ADCs or modulators, which is an oversampling ADC. In particular, various embodiments may relate to double sampling delta-sigma ADCs or modulators.

Various embodiments may provide double sampling delta-sigma modulators and the methods and schemes for the double sampling delta-sigma modulators. Various embodiments may provide an area efficient double sampling single operational transconductance amplifier (OTA) 2nd-order delta-sigma modulator with feed-forward path(s).

Various embodiments may provide an analog-to-digital converter, for example a delta-sigma modulator, incorporating a loop filter with a double sampling single (or reduced number) of operational transconductance amplifier (OTA) coupled with a compensating filter implemented in an integrated summer and analog-to-digital converter (ADC) block, together with a direct input feed-forward. The analog-to-digital converter may include a two-path or multi-path summer and ADC scheme that facilitates the implementation of architecture of the delta-sigma modulator of various embodiments. The architecture may be implemented with or without double sampling technique.

Various embodiments may provide a compensator implementation in the forward path, and requiring 1 DAC only (thereby only ⅓ DAC area) in the feedback path, thereby providing a lower input noise, a faster settling time or speed, and a relaxed linearity requirement.

Various embodiments may provide a two-path (or may be multi-path) implementation of switched capacitor (SC) summer and analog-to-digital converter (ADC) circuits for a double sampling modulator. Various embodiments may also provide a two-path (or may be multi-path) implementation of switched capacitor (SC) compensator, summer and analog-to-digital converter (ADC). The compensator may be integrated or incorporated in the two-path (or may be multi-path) summer and ADC.

Various embodiments may provide an implementation of a 3-level digital-to-analog converter (DAC) feedback that is inherently linear and mismatch insensitive, with or without double sampling technique, in a delta-sigma modulator.

Various embodiments may provide an area and power efficient digital-to-analog converter (DAC), without compromising resolution performance. Various embodiments may minimize silicon die area and power consumption of the switched capacitor (SC) digital-to-analog converter (DAC) to reduce cost and conserve power, for use in a variety of applications.

In order that the invention may be readily understood and put into practical effect, particular embodiments will now be described by way of examples and not limitations, and with reference to the figures.

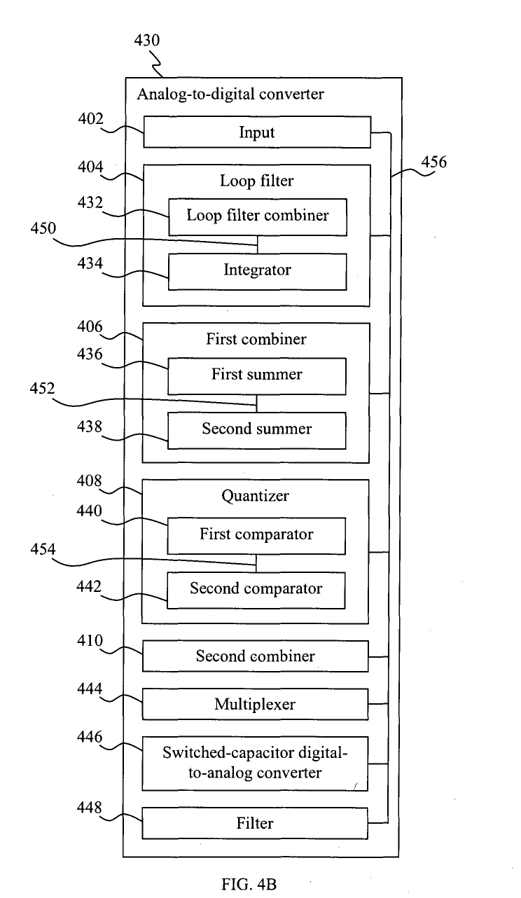

FIG. 4A shows a schematic block diagram of an analog-to-digital converter 400, according to various embodiments. The analog-to-digital converter 400 includes an input 402 configured to receive an input signal, a feed-forward path connected to the input 402 configured to feed forward the input signal, a processing path including a loop filter 404, wherein the loop filter 404 includes at least one local feedback path configured to feed back an output signal of the loop filter 404 to an input of the loop filter 404, a first combiner 406 configured to combine the input signal fed forward by the feed-forward path with an output of the processing path, a quantizer 408 configured to generate an output signal of the converter 400, a feed-back path configured to feed back the output signal, and a second combiner 410 wherein the processing path is connected to the second combiner 410 and the second combiner 410 is configured to combine the input signal with the fed back output signal of the converter 400 and supply the result of the combination to the processing path. The line represented as 412 is illustrated to show the relationship between the different components, which may include electrical coupling and/or mechanical coupling.

FIG. 4B shows a schematic block diagram of an analog-to-digital converter 430, according to various embodiments. The analog-to-digital converter 430 includes an input 402, a feed-forward path, a processing path including a loop filter 404, a first combiner 406, a quantizer 408, a feed-back path, and a second combiner 410, which may be similar to the embodiment as described in the context of FIG. 4A.

The loop filter 404 may include a first local feedback path configured to feed back an output of the loop filter 404 to an input of the loop filter 404 and a second local feedback path configured to feed back a delayed output of the loop filter 404 to an input of the loop filter 404. In other words, the at least one local feedback path of the loop filter 404 may include the first local feedback path and the second local feedback path.

The loop filter 404 may further include a loop filter combiner 432 configured to combine an input signal of the loop filter 404 with the fed back output signal of the loop filter 404. It should be appreciated that the loop filter combiner 432 may be the same as the second combiner 410 (i.e. the loop filter combiner 432 and the second combiner 410 are the same combiner) or may be separately provided, for example, the loop filter combiner 432 may be arranged in series with the second combiner 432 and configured to receive an output of the second combiner 432.

In various embodiments, the loop filter 404 includes an integrator 434 and the loop filter combiner 432 is configured to supply the result of the combination to the integrator 434. The integrator 434 may be configured to generate the output signal of the loop filter 404. The line represented as 450 is illustrated to show the relationship between the loop filter combiner 432 and the integrator 434, which may include electrical coupling and/or mechanical coupling.

In various embodiments, the first combiner 406 includes a first summer 436 and a second summer 438 and the quantizer 408 includes a first comparator 440 and a second comparator 442, wherein the output of the first summer 436 is supplied to the first comparator 440 and the output of the second summer 438 is supplied to the second comparator 442. The line represented as 452 is illustrated to show the relationship between the first summer 436 and the second summer 438, which may include electrical coupling and/or mechanical coupling, while the line represented as 454 is illustrated to show the relationship between the first comparator 440 and the second comparator 442, which may include electrical coupling and/or mechanical coupling. In various embodiments, the first combiner 406 and the quantizer 408 may be integrated.

The first summer 436 and the first comparator 440 may be oppositely clocked with respect to the second summer 438 and the second comparator 442. In other words, the first summer 436 and the first comparator 440 may be clocked with a first clock while the second summer 438 and the second comparator 442 may be clocked with a second clock, where the first clock and the second clock have opposite or alternate phases (i.e. 180° phase difference).

In various embodiments, the analog-to-digital converter 430 further includes a multiplexer 444 configured to multiplex the outputs of the first comparator 440 and the second comparator 442.

In various embodiments of the analog-to-digital converter 430, the first combiner 406 may include two or more summers (e.g. a first summer 436, a second summer 438, a third summer, a fourth summer or any higher number of summers) and the quantizer 408 may include two or more comparators (e.g. a first comparator 440, a second comparator 442, a third comparator, a fourth comparator or any higher number of comparators), wherein each summer is associated with a comparator and wherein the output of the summer is supplied to the comparator associated with the summer. In various embodiments, the analog-to-digital converter 430 further includes a multiplexer 444 configured to multiplex the outputs of the two or more comparators.

In FIG. 4B, the line represented as 456 is illustrated to show the relationship between the different components, which may include electrical coupling and/or mechanical coupling.

In the context of various embodiments of the analog-to-digital converter 400 and the analog-to-digital converter 430, the first combiner 406 is a multi-path combiner. Furthermore, each of the second combiner 410 and/or the loop filter combiner 432 may be a multi-path combiner.

In the context of various embodiments, each of the first combiner 406 and/or the second combiner 410 and/or the loop filter combiner 432 may be a “summer” or may include a “summer”, which is configured to perform summing operations of signals provided to the summer.

In the context of various embodiments of the analog-to-digital converter 400 and the analog-to-digital converter 430, the feedback path includes a digital-to-analog converter (DAC) or a switched-capacitor digital-to-analog converter (DAC) 446.

The switched-capacitor digital-to-analog converter 446 may be supplied with a three-level signal and the switched-capacitor digital-to-analog converter 446 includes three switches, wherein each switch is associated with one level of the three-level signal and the switch is switched on if the three-level signal has the level associated with the switch. In other words, the switched-capacitor digital-to-analog converter 446 may include a first switch, a second switch and a third switch, respectively associated with a first level, a second level and a third level of a three-level signal, where for example, the first switch may be switched on when the first level of the three-level signal is present or supplied.

In the context of various embodiments of the analog-to-digital converter 400 and the analog-to-digital converter 430, the processing path further includes a filter 448 configured to receive the output signal of the loop filter 404, and further configured to supply the output signal of the loop filter 404 and a delayed output signal of the loop filter 404 as the output of the processing path. In various embodiments, the filter 448 may function as a compensator or a compensating filter. The filter 448 may improve the stability of the analog-to-digital converter 400 and the analog-to-digital converter 430. In various embodiments, the first combiner 406, the quantizer 408 and the filter 448 may be integrated, or the filter 448 may be incorporated with or within the first combiner 406 and the quantizer 408.

In the context of various embodiments of the analog-to-digital converter 400 and the analog-to-digital converter 430, the quantizer 408 may be an analog-to-digital converter (ADC).

In the context of various embodiments, each of the analog-to-digital converter 400 and the analog-to-digital converter 430 may be a delta-sigma (ΔΣ) (or sigma-delta (ΣΔ)) modulator, for example a double sampling delta-sigma modulator.

In the context of various embodiments, the term “feed-forward path” may mean a path in which a signal may be fed forward in a direction from an input towards an output.

In the context of various embodiments, the term “feed-back path” may mean a path in which a signal may be fed back in a direction from an output towards an input.

In the context of various embodiments, the term “processing path” may mean a forward path in which a signal may be processed in a direction from an input towards an output.

In the context of various embodiments, the term “quantizer” may mean a circuit (e.g. any kind of a logic implementing entity, which may be special purpose circuitry, a hard-wired logic circuit, a programmable logic circuit or a processor executing software stored in a memory, firmware, or any combination thereof) configured to receive an input signal and to produce an output signal having output values that are discrete and finite.

In the context of various embodiments, the term “three-level signal” refers to a signal which may be represented by three levels (e.g. −1, 0, +1), as compared to a binary signal represented by two levels (e.g. 0, 1). Furthermore, the three-level signal may also be represented in a 2-bit binary/digital format, e.g. “00”, “01” and “10”.

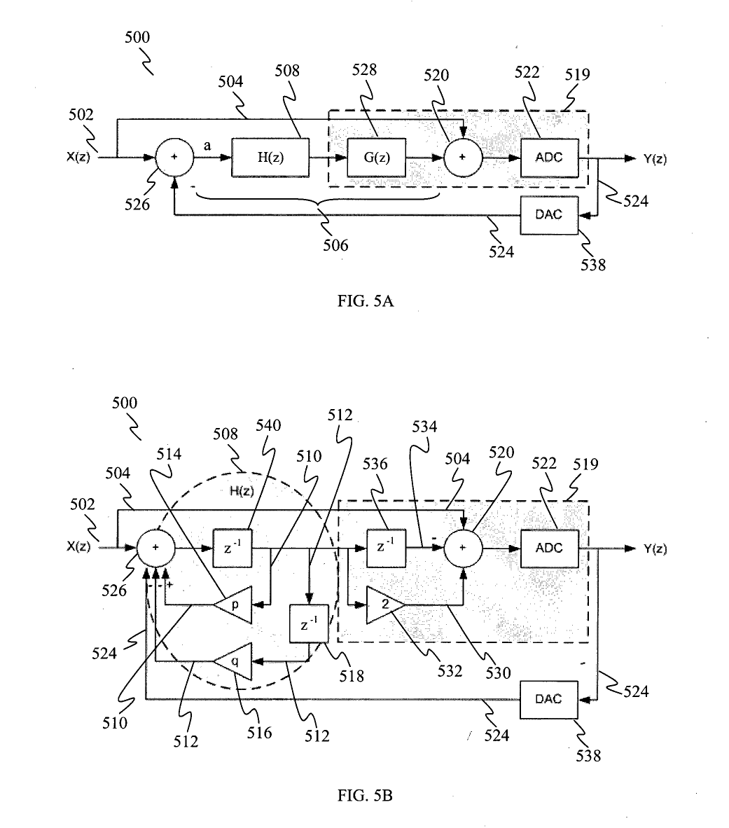

FIG. 5A shows a schematic block diagram of an analog-to-digital converter 500, according to various embodiments, while FIG. 5B shows a detailed schematic block diagram of the analog-to-digital converter 500 of the embodiment of FIG. 5A. The analog-to-digital converter 500 is a double sampling delta-sigma modulator with feed-forward. The detailed schematic block diagram of the analog-to-digital converter 500 shown in FIG. 5B illustrates a second-order delta-sigma modulator.

The analog-to-digital converter 500 includes an input 502 configured to receive an input signal X(z), a feed-forward path, as represented by 504, connected to the input 502 configured to feed forward the input signal X(z), a processing path, as represented by 506, including a loop filter, as represented by the H(z) block 508, wherein the loop filter 508 includes at least one local feedback path configured to feed back an output signal of the loop filter 508 to an input of the loop filter 508. As shown in FIG. 5B, the loop filter 508 may include a first local feedback path (e.g. p-path) 510 configured to feed back an output of the loop filter 508 to an input of the loop filter 508 and a second local feedback path (e.g. q-path) 512 configured to feed back a delayed output of the loop filter 508 to an input of the loop filter 508. The first local feedback path 510 includes a filter coefficient, p, as represented by 514, and the second local feedback path 512 includes a filter coefficient, q, as represented by 516, and a z⁻¹ block 518 representing a unit delay such that the second local feedback path 512 feeds back a delayed output of the loop filter 508 to an input of the loop filter 508.

The analog-to-digital converter 500 further includes a combiner and ADC block 519, including a first combiner 520 configured to combine the input signal X(z) fed forward by the feed-forward path 504 with an output of the processing path 506, a quantizer 522, in the form of an analog-to-digital (ADC), configured to generate an output signal Y(z) of the converter 500, a feed-back path 524 configured to feed back the output signal Y(z), a second combiner 526 wherein the processing path 506 is connected to the second combiner 526 and the second combiner 526 is configured to combine the input signal X(z) with the fed back output signal of the converter 500 and supply the result of the combination to the processing path 506.

The analog-to-digital converter 500 may further include a filter functioning as a compensator or a compensating filter, as represented by the G(z) block 528, along or in the processing path 506, the compensator 528 being configured to receive the output signal of the loop filter 508. As shown in FIG. 5B, the compensator 528 may be further configured to supply the output signal of the loop filter 508 along a path 530 including a filter coefficient of 2, as represented by 532, and a delayed output signal of the loop filter 508 as the output of the processing path 506 along a path 534 to the first combiner 520. The path 534 includes a z⁻¹ block 536 representing a unit delay such that the compensator 528 provides a delayed output signal of the loop filter 508 to the first combiner 520. The compensator 528 may be incorporated or implemented within the combiner and ADC block 519. The compensator 528 may improve the stability of the analog-to-digital converter 500. In various embodiments, incorporating the compensator 528 along or in the processing path 506 enables the use of smaller capacitors to implement G(z), thereby minimising the use of die or silicon area, and also requires a single DAC 538 in the feedback path 524. In contrast, having a compensator in the feedback path requires a larger capacitor area (3×DAC capacitor areas) and two DACs, compared to various embodiments (e.g. analog-to-digital converter 500), which increases the kT/C noise, power consumption and silicon area.

The analog-to-digital converter 500 may further include a digital-to-analog converter (DAC) 538, for example a switched-capacitor (SC) digital-to-analog converter, along or in the feedback path 524.

As shown in FIG. 5B, the loop filter 508 may include a z⁻¹ block 540 representing a unit delay along the processing path 506 to generate a delayed version of the input signal X(z) provided to the loop filter 508 as the output signal of the loop filter, and as input signals provided to the p-path 510 and the q-path 512.

As illustrated in FIG. 5B, the second combiner 526 also acts as a loop filter combiner configured to combine an input signal of the loop filter 508 with the fed back output signal of the loop filter 508. In further embodiments, a separate loop combiner may be provided, for example in series with the second combiner 526 so as to receive an output signal of the second combiner 526 as an input signal of the loop filter 508 and the loop filter combiner, so as to combine the received input signal X(z) with the fed back output signal of the loop filter 508 via the p-path 510 and the q-path 512.

In various embodiments, the first combiner 520, the quantizer 522 and the compensator 528 may be integrated or implemented as a single block.

As illustrated in FIG. 5B, the first combiner 520 is a multi-path combiner. The second combiner 526 is also a multi-path combiner.

Each of the quantizer 522 and the DAC 538 may be 1-bit (single-bit) or multi-bit, with the latter providing a smaller quantization error.

The analog-to-digital converter 500 employs a single operational transconductance amplifier (OTA) to implement the loop filter H(z) 508, thereby combining the advantages of a single OTA double sampling delta-sigma modulator and a feed-forward architecture. The feed-forward architecture includes a a feed-forward path connected to the input configured to feed forward the input signal. In addition, the combination of the compensator 528, the first combiner 520 and the quantizer 522 is employed in a multi-path implementation without using any additional OTA for the compensator 528. Accordingly, the analog-to-digital converter 500 may achieve a robust delta-sigma modulator that is more area efficient and power efficient.

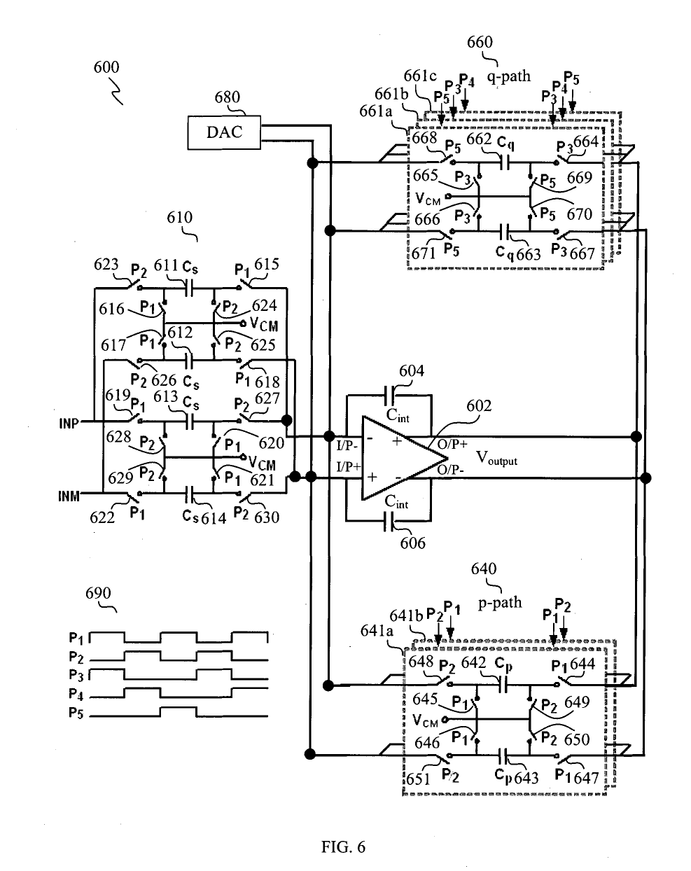

FIG. 6 shows a schematic diagram of a circuit implementation 600 of the loop filter, according to various embodiments. FIG. 6 shows a fully-differential implementation of the loop filter using a single double sampling OTA and double sampling switched capacitor (SC) circuits, which may result in area efficient (i.e. requires less die or silicon area) and lower power consumption.

The loop filter 600 is a second order filter and the circuit 600 includes an amplifier 602 with a first integrating capacitor (Cᵢₙₜ) 604 coupled between a negative input (I/P−) and a positive output (O/P+) of the amplifier 602, and a second integrating capacitor (Cᵢₙₜ) 606 coupled between a positive input (I/P+) and a negative output (O/P−). The amplifier 602, the first integrating capacitor 604 and the second integrating capacitor 606 may function as an integrator and generate an output signal of the loop filter. Therefore, the H(z) block 508 of FIGS. 5A and 5B may alo be referred to as an integrator block.

The circuit 600 further includes an input circuit 610 coupled to the negative input (I/P−) and the positive input (I/P+) of the amplifier 602, a p-path circuit 640 coupled to the negative input (I/P−), the positive input (I/P+), the negative output (O/P−) and the positive output (O/P+) of the amplifier 602 for providing feedback to the amplifier 602, a q-path circuit 660 coupled to the negative input (I/P−), the positive input (I/P+), the negative output (O/P−) and the positive output (O/P+) of the amplifier 602 for providing feedback to the amplifier 602, and a digital-to-analog converter (DAC) 680 coupled to the negative input (I/P−) and the positive input (I/P+) of the amplifier 602, the p-path circuit 640 and the q-path circuit 660.

FIG. 6 further shows a non-limiting example of a timing diagram 690, for example of clock signals P₁, P₂, P₃, P₄ and P₅, which may be used to control the sequence of operation of the circuit 600. The clock signals P₁ and P₂ may be complementary to each other as a function of time, and used to control the operation of the input circuit 610 and the p-path circuit 640, while the clock signals P₃, P₄ and P₅ are sequential as a function of time, and used to control the operation of the q-path circuit 660. However, it should be appreciated that other clock signals having different relationships to each other may be used.

The input circuit 610 receives input signals, INP and INM, which are sampled by two sets of sampling capacitors (Cₛ) respectively having a pair of sampling capacitors (Cₛ) 611, 612 and another pair of sampling capacitors (Cₛ) 613, 614, controlled by the clock signals P₁ and P₂, for functioning as a double sampling SC circuit.

When the clock signal P₁ is asserted (‘high’), switches 615, 616, 617, 618, 619, 620, 621, 622, are closed such that the sampling capacitors 613, 614 are charged while the sampling capacitors 611, 612 are discharged with the stored charges transferred respectively to the first integrating capacitor 604 and the second integrating capacitor 606.

When the clock signal P₂ is asserted (‘high’), switches 623, 624, 625, 626, 627, 628, 629, 630, are closed such that the sampling capacitors 611, 612 are charged while the sampling capacitors 613, 614 are discharged with the stored charges transferred respectively to the first integrating capacitor 604 and the second integrating capacitor 606.

As shown in FIG. 6, the p-path circuit 640 may be realized by using two sets of switched capacitor circuits 641a, 641b, having sampling capacitors (Cₚ) clocked with alternate clock phases P₁ and P₂, where each set of switched capacitor circuits 641a, 641b has a pair of sampling capacitors (Cₚ), while the q-path circuit 660 may be implemented by using three sets of switched capacitor circuits 661a, 661b, 661c, having sampling capacitors (C_{q}) clocked with three-phase clock signals P₃, P₄ and P₅, where each set switched capacitor circuits 661a, 661b, 661c has a pair of sampling capacitors (C_{q}).

For the p-path circuit 640, the switched capacitor circuit 641a includes a pair of sampling capacitors (e.g. Cₚ₁) 642, 643, and eight switches 644, 645, 646, 647, 648, 649, 650, 651, coupled to each other such that the switches 644, 645, 646, 647 are closed when the clock signal P₁ is asserted, for communication with the negative output (O/P−) and the positive output (O/P+) of the amplifier 602, and that the switches 648, 649, 650, 651 are closed when the clock signal P₂ is asserted, for communication with the negative input (I/P−) and the positive input (I/P+) of the amplifier 602.

The switched capacitor circuit 641b includes a corresponding structure or topology similar to that of the switched capacitor circuit 641a, including a pair of sampling capacitors (e.g. Cₚ₂) (not shown), but where the switches (not shown) of the switched capacitor circuit 641b corresponding to switches 648, 649, 650, 651 are closed when the clock signal P₁ is asserted, for communication with the negative input (I/P−) and the positive input (I/P+) of the amplifier 602, while the switches (not shown) of the switched capacitor circuit 641b corresponding to switches 644, 645, 646, 647 are closed when the clock signal P₂ is asserted, for communication with the negative output (O/P−) and the positive output (O/P+) of the amplifier 602.

In various embodiments, the operation of the p-path circuit 640 may be similar to the sampling of the input signals INP and IMP by the input circuit 610, in which two sets of switched capacitor circuits 641a, 641b, having sampling capacitors (Cₚ) (e.g. 642, 643) are clocked with alternate non-overlapping clock phases P₁ and P₂ to sample the loop filter output (Voutput) in both P₁ and P₂ clock phases in a double sampling operation. The output (Voutput) being sampled is then fed back to the loop filter, to the negative input (I/P−) and the positive input (I/P+) of the amplifier 602, thereby implementing the p-path feedback 510 as shown in the embodiment of FIG. 5B.

For the q-path circuit 660, the switched capacitor circuit 661a includes a pair of sampling capacitors (e.g. C_{q1}) 662, 663, and eight switches 664, 665, 666, 667, 668, 669, 670, 671, coupled to each other such that the switches 664, 665, 666, 667 are closed when the clock signal P₃ is asserted, for communication with the negative output (O/P−) and the positive output (O/P+) of the amplifier 602, and that the switches 668, 669, 670, 671 are closed when the clock signal P₅ is asserted, for communication with the negative input (I/P−) and the positive input (I/P+) of the amplifier 602.

The switched capacitor circuit 661b includes a corresponding structure or topology similar to that of the switched capacitor circuit 661a, including a pair of sampling capacitors (e.g. C_{q2}) (not shown), but where the switches (not shown) of the switched capacitor circuit 661b corresponding to switches 664, 665, 666, 667 are closed when the clock signal P₄ is asserted, for communication with the negative output (O/P−) and the positive output (O/P+) of the amplifier 602, while the switches (not shown) of the switched capacitor circuit 661b corresponding to switches 668, 669, 670, 671 are closed when the clock signal P₃ is asserted, for communication with the negative input (I/P−) and the positive input (I/P+) of the amplifier 602.

The switched capacitor circuit 661c includes a corresponding structure or topology similar to that of the switched capacitor circuit 661a, including a pair of sampling capacitors (e.g. C_{q3}) (not shown), but where the switches (not shown) of the switched capacitor circuit 661c corresponding to switches 664, 665, 666, 667 are closed when the clock signal P₅ is asserted, for communication with the negative output (O/P−) and the positive output (O/P+) of the amplifier 602, while the switches (not shown) of the switched capacitor circuit 661c corresponding to switches 668, 669, 670, 671 are closed when the clock signal P₄ is asserted, for communication with the negative input (I/P−) and the positive input (I/P+) of the amplifier 602.

The q-path circuit 660 may be implemented by using three sets of switched capacitor circuits 661a, 661b, 661c, having sampling capacitors (C_{q}) (e.g. 662, 663) clocked with three-phase non-overlapping clock signals P₃, P₄ and P₅. Using the switched capacitor circuit 661a as an example, the output (Voutput) is first sampled during P₃ onto the pair of sampling capacitors 662, 663. In the subsequent P₄ clock phase, the output voltage previously sampled during P₃ on the sampling capacitors 662, 663 is maintained. In the following P₅ clock phase, the sampled output voltage is fed back to the loop filter, to the negative input (I/P−) and the positive input (I/P+) of the amplifier 602, thereby implementing the q-path feedback 512 as shown in the embodiment of FIG. 5B, and achieving effectively a 1-cycle delay (as represented by 518). The sampling capacitors of the switched capacitor circuit 661b are controlled by the clock signals P₄ and P₃, and the sampling capacitors of the switched capacitor circuit 661c are controlled by the clock signals Pₛ and P₄, such that the output (Voutput) is sampled in every clock phase P₃, P₄ and P₅ by the q-path circuit 660.

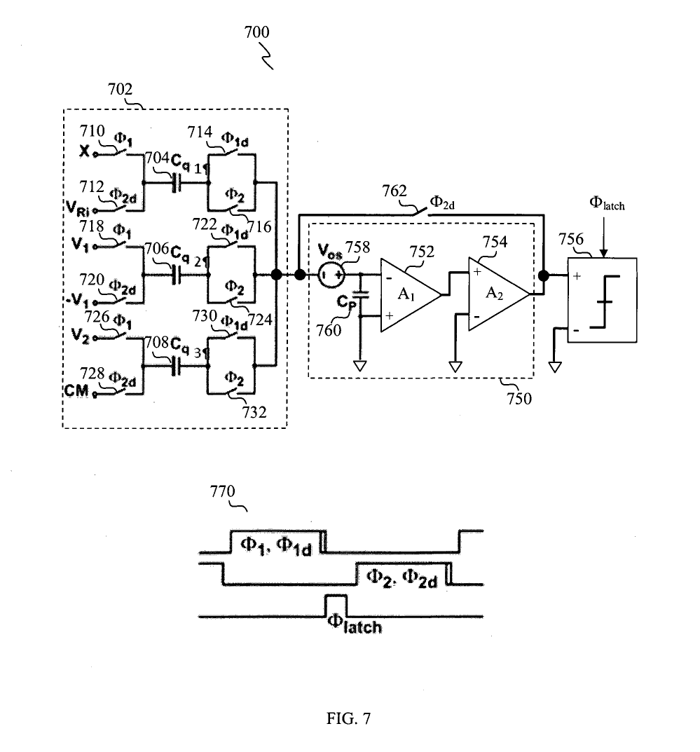

FIG. 7 shows a schematic diagram of a circuit implementation 700 of the first combiner and the quantizer, according to various embodiments, in a single-ended implementation. The circuit 700 includes a switched-capacitor network 702 with inputs weighted by the capacitor ratios, defined by the capacitors C_{q1} 704, C_{q2} 706 and C_{q3} 708, followed by a pre-amplifier stage 750 and a latched comparator 756.

The switched-capacitor network 702 includes three capacitors C_{q1} 704, C_{q2} 706 and C_{q3} 708. The capacitor C_{q1} 704 is coupled between two pairs of switches 710, 712, and 714, 716, the capacitor C_{q2} 706 is coupled between two pairs of switches 718, 720, and 722, 724, while the capacitor C_{q3} 708 is coupled between two pairs of switches 726, 728, and 730, 732.

The circuit 700 includes a pre-amplifier stage 750 including a first amplifier (A₁) 752, and a second amplifier (A₂) 754. The circuit 700 further includes a latched comparator 756. The pre-amplifier stage 750 is coupled between an output of the switched-capacitor network 702 and the positive input of the comparator 756. The output of the amplifier 752 is coupled to the positive input of the amplifier 754, while the output of the amplifier 754 is coupled to the positive input of the comparator 756. In various embodiments, the comparator 756 may be used to detect whether the input received by the comparator 756 is above or below a certain threshold voltage.

In order to model the non-ideal input-referred offset of the pre-amplifier stage 750 and the associated parasitic capacitances at the input node, an offset (V_{OS}) 758 coupled between the output of the switched-capacitor network 702 the negative input of the amplifier 752, and a capacitor (Cₚ) 760 coupled between the negative input and the positive input of the amplifier 752 are illustrated in FIG. 7 for understanding purposes. It should be appreciated that V_{OS} 758 and Cₚ 760 are not present in the circuit 700, and that no components are incorporated in the circuit to implement V_{OS} 758 and Cₚ 760.

The circuit 700 further includes a switch 762 coupled between the output of the switched-capacitor network 702 and the output of the amplifier 754. In other words, the switch 762 is coupled between the input and output of the pre-amplifier stage 750. The positive input of the amplifier 752, the negative input of the amplifier 754 and the negative input of the comparator 756 are grounded.

FIG. 7 further shows a non-limiting example of a timing diagram 770, for example of clock signals Φ₁, Φ_{1d}, Φ₂, Φ_{2d} and Φ_{latch}, which may be used to control the sequence of operation of the circuit 700. The clock signals Φ₁, Φ_{1d}, and Φ₂, Φ_{2d}, are asserted in a non-overlapping manner, i.e. when clock signals Φ₁, Φ_{1d}, are asserted (‘high’), the clock signals Φ₂, Φ_{2d}, are not asserted (‘low’) and vice versa. Furthermore, the clock signal, Φ_{latch}, for latching the comparator 756 is asserted during the period when the clock signals Φ₁, Φ_{1d}, Φ₂, Φ_{2d} are ‘low’ or not asserted. Therefore, the clock signal, Φ_{latch}, may be asserted in a period between the end of the clock signals Φ₁, Φ_{1d} being asserted and before the clock signals Φ₂, Φ_{2d} are asserted.

For the switched-capacitor network 702, the switches 710, 718, 726 are closed when the clock signal Φ₁ is asserted, the switches 714, 722, 730 are closed when the clock signal Φ_{1d} is asserted, the switches 716, 724, 732 are closed when the clock signal Φ₂ is asserted, and the switches 712, 720, 728 are closed when the clock signal Φ_{2d} is asserted. In addition, the switch 762 is closed when the clock signal Φ_{2d} is asserted.

During when the clock signals Φ₂ and Φ_{2d} are asserted, the comparator 756 is reset and the pre-amplifier 750 may be configured as a unity gain amplifier, while sampling the input-referred offset V_{OS} 758 on the parasitic capacitor Cₚ 760, and in addition, V_{Ri} (a reference voltage), ‘−V₁’ and the common mode reference CM are sampled onto the capacitors C_{q1} 704, C_{q2} 706 and C_{q3} 708 respectively.

During when the clock signals Φ₁ and Φ_{1d} are asserted, the bottom plates of the capacitors C_{q1} 704, C_{q2} 706 and C_{q3} 708 are switched to ‘X’, ‘V₁’ and ‘V₂’ respectively, while the pre-amplifier 750 amplifies the resulting composite input signal given by Equation 6 below:

$$\frac{{C}_{q 1}}{{C}_{T}} [ X ( n ) - {V}_{Ri} ] + 2 \frac{{C}_{q 2}}{{C}_{T}} {V}_{1} ( n ) + \frac{{C}_{q 3}}{{C}_{T}} {V}_{2} ( n ) \qquad ( Equation 6 )$$

where C_{T}=C_{q1}+C_{q2}+C_{q3}+Cₚ.

As the comparator 756 detects the sign of the pre-amplifier input given in Equation 6, only the ratio among the capacitors C_{q1} 704, C_{q2} 706 and C_{q3} 708 is used in determining the comparator output.

In various embodiments, ‘V₂’ and ‘CM’ may be swapped in order to obtain an input to the pre-amplifier 750 given by Equation 7 below, which shows that a half-cycle delay and inverted V₂ is sampled.

$$\frac{{C}_{q 1}}{{C}_{T}} [ X ( n ) - {V}_{Ri} ] + 2 \frac{{C}_{q 2}}{{C}_{T}} {V}_{1} ( n ) - \frac{{C}_{q 3}}{{C}_{T}} {V}_{2} ( n - \frac{{1}^{′}}{2} ) . \qquad ( Equation 7 )$$

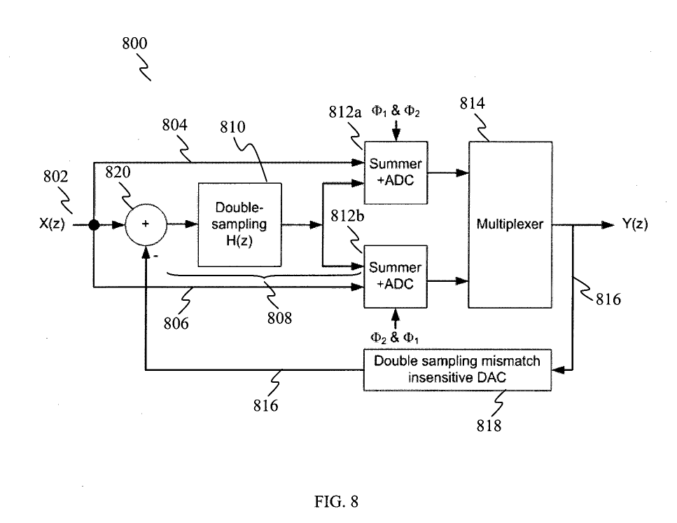

Equation 7 forms the basis of a two-path summer and comparator implementation of various embodiments, as shown in FIG. 8 illustrating a schematic block diagram of an analog-to-digital converter 800 incorporating two-path summers and analog-to-digital converters, according to various embodiments. For double sampling implementation, a half-cycle delay is equivalent to a 1-cycle delay which may be used to implement G(z)=2−z⁻¹ using two-path summer and ADC circuits clocked with alternate clock phases, without using extra storage capacitors.

The analog-to-digital converter 800 includes an input 802 configured to receive an input signal X(z), a first feed-forward path, as represented by 804, and a second feed-forward path, as represented by 806, connected to the input 802 configured to feed forward the input signal X(z), a processing path, as represented by 808, including a loop filter, as represented by the double sampling H(z) block 810. The loop filter 810 may be similar to the loop filter 508 of the embodiment as described in the context of FIGS. 5A and 5B.

The analog-to-digital converter 800 further includes a first summer and analog-to digital converter (ADC), as represented by block 812a, and a second summer and analog-to digital converter (ADC), as represented by block 812b. The first summer and ADC block 812a is configured to combine the input signal X(z) fed forward by the first feed-forward path 804 with an output of the processing path 808, and to generate an output signal. The second summer and ADC block 812b is configured to combine the input signal X(z) fed forward by the second feed-forward path 806 with an output of the processing path 808, and to generate an output signal.

Each of the ADCs of the first summer and ADC block 812a and the second summer and ADC block 812b includes a comparator. Furthermore, each of the first summer and ADC block 812a and the second summer and ADC block 812b may have a circuit implementation of the embodiment of FIG. 7.

By comparing the embodiments of FIGS. 5A and 5B with FIG. 8, the first summer and ADC block 812a and the second summer and ADC block 812b of the embodiment of FIG. 8 may be equivalent to the first combiner 520 and the quantizer 522 of the embodiments in that the first combiner 520 may include a first summer of the first summer and ADC block 812a and a second summer of the second summer and ADC block 812b, while the quantizer 522 may include a first comparator of the first summer and ADC block 812a and a second comparator of the second summer and ADC block 812b. The output of the first summer is supplied to the first comparator and the output of the second summer is supplied to the second comparator.

The first summer and ADC 812a and the second summer and ADC 812b may be oppositely clocked, for example with clock signals Φ₁ and Φ₂, having opposite phases (180° phase difference), i.e. the first summer and the first comparator are oppositely clocked with respect to the second summer and the second comparator.

The analog-to-digital converter 800 further includes a multiplexer 814 configured to multiplex the outputs of the first comparator of the first summer and ADC 812a and the second comparator of the second summer and ADC 812b, to produce an output signal Y(z).

The analog-to-digital converter 800 further includes a feed-back path 816 configured to feed back the output signal Y(z). The feedback path 816 includes a switched-capacitor digital-to-analog converter (DAC), e.g. a double sampling mismatch insensitive DAC 818.

The analog-to-digital converter 800 further includes a second combiner 820 wherein the processing path 808 is connected to the second combiner 820 and the second combiner 820 is configured to combine the input signal X(z) with the fed back output signal of the converter 800 and supply the result of the combination to the processing path 808.

While not shown, the analog-to-digital converter 800 includes a compensator (e.g. the G(z) block 528 of FIG. 5A, e.g. including the path 530 including a filter coefficient 532, and the path 534 including a z⁻¹ block 536 representing a unit delay of FIG. 5B), along or in the processing path 808, configured to receive the output signal of the loop filter 810, and to supply a respective signal to the first summer and ADC 812a and the second summer and ADC 812b. In further embodiments, the compensator may be implemented together or integrated with the first summer and ADC block 812a and the second summer and ADC block 812b. In further embodiments, the two-path summer and ADC circuits enable compensator implementation in the processing path, for example the function of the compensator may be incorporated in the circuits of the two-path summer and ADC circuits.

By using two sets of identical summers and comparators clocked with alternate clock phases (Φ₁ and Φ₂) as shown in FIG. 8, a half-cycle delay in V₂ as per Equation 7 becomes a 1-cycle delay required for implementing the compensator in a double sampling SC circuit, thereby giving an input according to Equation 8:

$$\frac{{C}_{q 1}}{{C}_{T}} [ X ( n ) - {V}_{Ri} ] + 2 \frac{{C}_{q 2}}{{C}_{T}} {V}_{1} ( n ) - \frac{{C}_{q 3}}{{C}_{T}} {V}_{2} ( n - 1 ) . \qquad ( Equation 8 )$$

While FIG. 8 shows a schematic block diagram of an analog-to-digital converter 800 incorporating two-path summer and analog-to-digital converters, it should be appreciated that the analog-to-digital converter 800 may incorporate multi-path summers and analog-to-digital converters, for example where the first combiner 520 may include two or more summers while the quantizer 522 may include two or more comparators, wherein each summer is associated with a comparator and wherein the output of the summer is supplied to the comparator associated with the summer. The outputs of the two or more comparators may then be multiplexed by a multiplexer (e.g. 814).

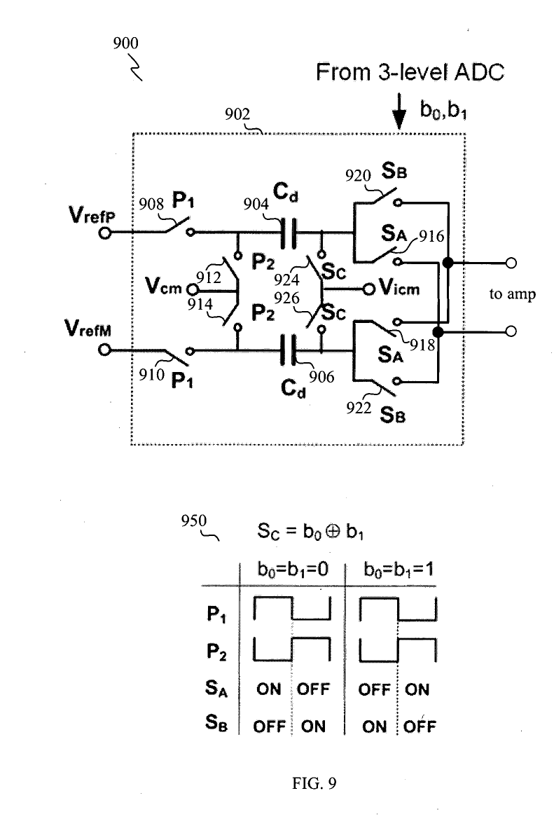

In various embodiments, with a feed-forward architecture, H(z) only processes the noise-shaped quantization noise E(z). In order to reduce the quantization error without using any dynamic element matching (DEM) or calibration schemes, a multi-bit ADC, in the form of an inherently linear mismatch insensitive 3-level double sampling SC DAC, may be employed to reduce E(z). FIG. 9 shows a schematic diagram of a circuit implementation 900 of a three-level switched capacitor (SC) digital-to-analog converter (DAC), according to various embodiments. The circuit 900 may be implemented for the DAC 538 (FIGS. 5A and 5B), the DAC 680 (FIG. 6) and the DAC 818 (FIG. 8). In embodiments employing the circuit 900, the ADC 522 (FIGS. 5A and 5B) and the ADCs in the first summer and ADC 812a and the second summer and ADC 812b (FIG. 8) are 3-level ADC.

The circuit 900 receives the outputs of a 3-level ADC, represented by the thermometer code b₁b₀ and sets one of the 3 non-overlapping switch control signals S_{A}, S_{B} and S_{C} to “ON” depending on the clock phases or signals P₁ and P₂, as shown in the truth table 950. The switch control signal S_{C} is a result of an “exclusive or” (XOR, ⊕) operation of b₀ and b₁. Compared to a 2-level feedback, the circuit 900 includes an additional zero level feedback realized by setting S_{C} to “ON” to close the relevant switches while keeping S_{A} and S_{B} “OFF” to open the relevant switches. The control signals S_{A}, S_{B} and S_{C} may be asserted based on an output from a quantizer of a 3-level ADC. The control signals S_{A} and S_{B} may control the polarity of feedback during both P₁ and P₂.

The circuit 900 includes a single switched capacitor structure 902 with two sampling capacitors (C_{d}) 904, 906, and a plurality of switches 908, 910, 912, 914, 916, 918, 920, 922, 924, 926. The switches 908, 910 are closed when the clock signal P₁ is asserted (“high”) such that the capacitor 904 is in electrical communication with a positive reference voltage (V_{refP}) while the capacitor 906 is in electrical communication with a negative reference voltage (V_{refM}). The switches 912, 914 are closed when the clock signal P₂ is asserted (“high”) such that the capacitor 904 and the capacitor 906 are in electrical communication with a voltage (V_{CM}). In addition, the switches 916, 918 are closed when S_{A} is asserted, the switches 920, 922 are closed when S_{B} is asserted, and the switches 924, 926 are closed when S_{C} is asserted. When the switches 924, 926 are closed, a connection may be provided to a voltage (V_{iCM}). V_{CM} and V_{iCM} refer to the common mode voltage and the input common mode voltage respectively, which may be considered as the “ground” for differential signals and are required for the proper operation of circuits. However, these voltages may be cancelled out in fully differential circuits.

Based on the embodiment of FIG. 6 as a non-limiting example, when the clock signal P₁ is asserted, the charges on the capacitors 904, 906 may be transferred to the first integrating capacitor 604 and the second integrating capacitor 606 through switches 916, 918, 920, 922, depending on whether S_{A} or S_{B} is asserted, while the capacitors 904, 906 are also charged, as the switches 908, 910 are closed. When the clock signal P₂ is asserted, the capacitors 904, 906 are discharged with the charges transferred to the first integrating capacitor 604 and the second integrating capacitor 606 through switches 916, 918, 920, 922, depending on whether S_{A} or S_{B} is asserted.

Instead of using two sets of sampling capacitors to realize a conventional double sampling DAC, the circuit 900 uses only one set of sampling capacitors (C_{d}) 904, 906, working in both the P₁ and P₂ clock phases, thereby eliminating the mismatch between capacitors of different sets which may produce a phase-dependent gain error. In addition, the circuit 900 not only reduces the quantization error by approximately 6 dB, but also is inherently linear, without requiring any DEM or calibration schemes, and with negligible area overhead.

In various embodiments, the single set of sampling capacitors (C_{d}) 904, 906, work in both the P₁ and P₂ clock phases to provide DAC feedback of either +(V_{refP}−V_{refM}) or −(V_{refP}−V_{refM}). The third level (the zero level) feedback is achieved through switches 924, 926, controlled by S_{C} when no charges on the sampling capacitors (C_{d}) 904, 906 are transferred or fed back to the amplifier (e.g. amplifier 602 of FIG. 6), thereby achieving “zero” level DAC feedback.

In various embodiments, the circuit 700 may be employed to realise a 3-level ADC. As the comparator 756 of the circuit 700 may be used to detect whether the input received by the comparator 756 is above or below a certain threshold voltage, two comparators with different threshold voltages may be employed to implement the 3-level ADC.

Simulation and measurement results for the analog-to-digital converter of various embodiments will now be described. System level simulations were performed using Simulink to determine the performance of the analog-to-digital converter of various embodiments.

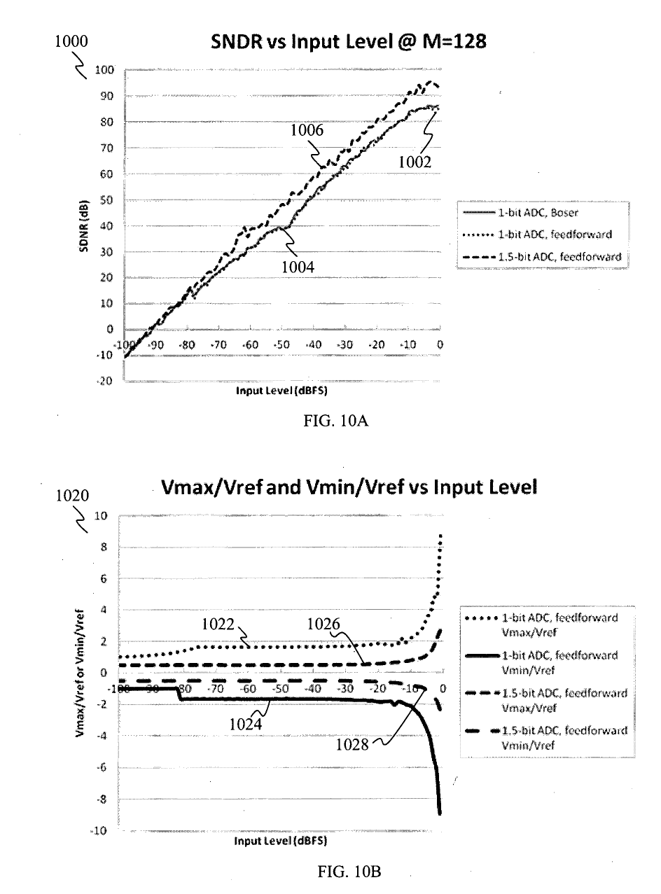

FIG. 10A shows a plot 1000 of simulated results of signal-to-noise and distortion ratio (SNDR) against input level for an oversampling ratio of 128, according to various embodiments.

The result 1002 shows that the analog-to-digital converter of various embodiments employing a 2-level ADC (denoted as “1-bit ADC”) achieves a similar performance as that of a conventional second-order delta-sigma modulator (denoted as “Boser”) as shown by the result 1004. When a 3-level ADC (denoted as “1.5-bit ADC”) is used in the analog-to-digital converter of various embodiments, the result 1006 shows that the SNDR improves by between about 5 dB and about 10 dB as compared to that of a 1-bit ADC (result 1002).

In addition, employing a 3-level ADC provides a reduced loop filter output signal excursion as illustrated in FIG. 10B. FIG. 10B shows a plot 1020 of simulated results of loop filter outputs (Vmax and Vmin) against input level, according to various embodiments. The plot 1020 shows the results for Vmax/Vref 1022 and Vmin/Vref 1024 for an analog-to-digital converter of various embodiments employing a 2-level ADC (denoted as “1-bit ADC”) and the results for Vmax/Vref 1026 and Vmin/Vref 1028 for an analog-to-digital converter of various embodiments employing a 3-level ADC (denoted as “1.5-bit ADC”).

As a result of the feed-forward architecture of the analog-to-digital converter of various embodiments, the loop filter of the analog-to-digital converter only needs to process the quantization error, which is reduced by about 6 dB using a 1.5-bit ADC instead of a 1-bit ADC.

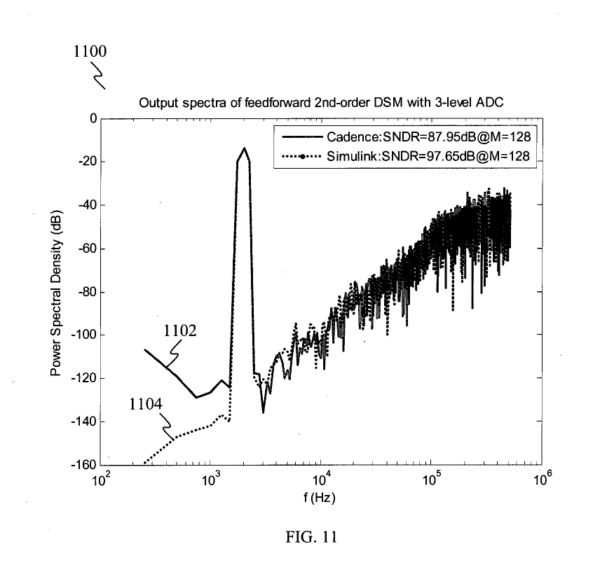

The analog-to-digital converter of various embodiments has been designed and implemented using a 0.18 μm CMOS 1P6M process. The 1P6M process offers one polysilicon and six metal layers. With a supply voltage of 1 V, the analog-to-digital converter achieves an SNDR of about 87.95 dB at an oversampling ratio of 128 for a 2 kHz input level of −1.94 dBFS (80% of full scale) (i.e. −1.94 dB with respect to the full scale reference level) when clocked at 512 kHz (effective sampling rate=1.024 MHz due to double sampling). FIG. 11 shows a plot 1100 of output spectra for the analog-to-digital converter of various embodiments, for an input of about −1.94 dBFS. The analog-to-digital converter was a second order delta-sigma modulator employing a 3-level ADC. The plot 1100 shows the output spectra of the actual circuit implementation (cadence) 1102 and the system level simulation (simulink) 1104. The result 1102 shows an SNDR of about 87.95 dB against 97.65 dB for the simulated result 1104.

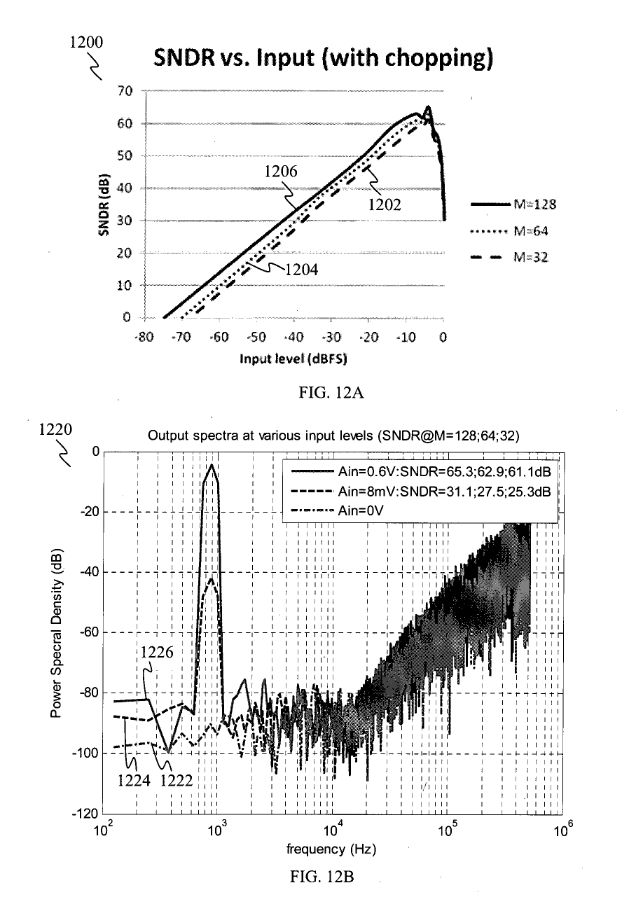

FIG. 12A shows a plot 1200 of measured results of signal-to-noise and distortion ratio (SNDR) against input level for different oversampling ratios, according to various embodiments. The plot 1200 shows the results of an analog-to-digital converter of various embodiments employing a 3-level ADC (1.5-bit ADC) for oversampling ratios M=32 1202, M=64 1204 and M=128 1206.

FIG. 12B shows a plot 1220 of measured output spectra for the analog-to-digital converter of various embodiments for different input levels. The plot 1220 was obtained using similar measurement parameters as those used to obtain the result 1102 of plot 1100 (FIG. 11).

The plot 1220 shows the output spectra of an analog-to-digital converter of various embodiments employing a 3-level ADC (1.5-bit ADC) for input levels Ain=0 V 1222, Ain=8 mV 1224 and Ain=0.6 V 1226.

A peak SNDR of about 65.3 dB at an input level of −4.44 dBFS (0.6V) at an oversampling ratio, M=128 may be observed. In addition, the dynamic ranges achieved are approximately 74.7 dB, 69.9 dB and 67.6 dB at M=128, 64 and 32 respectively. The dynamic range shows the usable input range, from the lowest (i.e. when SNDR=0 dB) to the maximum input levels as shown approximately by the differences between the x-axis intercepts and around 0 dBFS input in FIG. 12A. Based on a power consumption of about 17 μW and the DR values mentioned, the figure-of-merits (FOMs) are about 479 fJ/step, 416 fJ/step and 271 fJ/step at M=128, 64 and 32 respectively. The FOM may be calculated based on FOM=Power/(2^{ENOB}×2×f_{B}), where f_{B} is the bandwidth and ENOB=(DR_{dB}−1.76)16.02, where ENOB refers to the effective number of bits. The FOM compares the performances of different ADCs. It is similar to a normalised figure or value which takes into account the different ENOBs, bandwidths and power consumptions.

Various embodiments may provide a double sampling two-path 3-level ADC, having a second order cascade-integrator feed-forward (CIFF) switched capacitor (SC) 3-level topology or architecture, implemented using a 0.18 μm CMOS process. The ADC may have the parameters of f_{S}=1.024 MHz, f_{B}=4-16 kHz, oversampling rate (OSR)=32-128, dynamic range (DR)=67.6-80 dB, VDD=0.9-1 V, power=15-17 μW, figure-of-merit (FOM)=230-271 fJ/conv-step and core area=0.06 mm², with the OTA and capacitor area=0.045 mm².

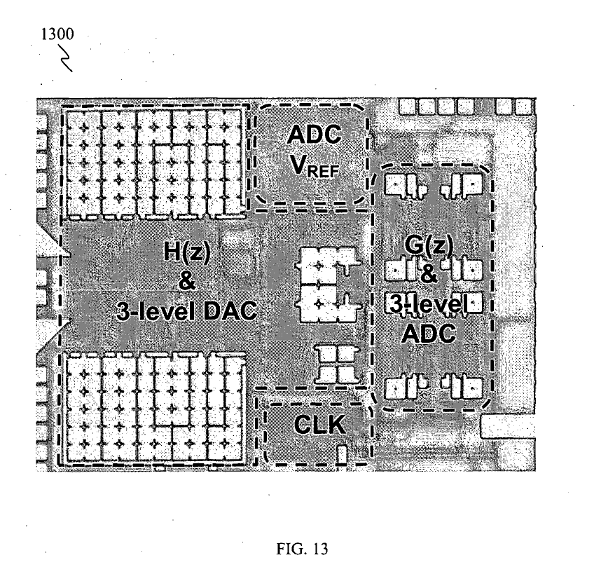

FIG. 13 shows a chip microphotograph of the analog-to-digital converter of various embodiments.

The analog-to-digital converter (ADC) of various embodiments employs a second-order delta-sigma modulator as a non-limiting example, and may provide the following advantages:
(1) The analog-to-digital converter (ADC) of various embodiments includes the advantages of using a single operational transconductance amplifier (OTA) double sampling architecture with only a single digital-to-analog (DAC) feedback path, resulting in a lower input-referred kT/C noise penalty and less loading to the OTA input, thereby providing a higher switched capacitor (SC) integrator settling speed (i.e. faster OTA settling time in the loop filter).
(2) The feed-forward path and the processing path in the analog-to-digital converter (ADC) of various embodiments relaxe the linearity requirement of the OTA used in the loop filter, as represented by the H(z) block, as the loop filter only needs to process the noise-shaped quantization error E(z) instead of both the input X(z) and E(z) according to Equation 5.
(3) As the input to H(z) only contains the quantization error E(z), the use of a multi-bit ADC may directly reduce E(z), which limits the output of H(z) irrespective of the magnitude of input X(z). This may allow for less or no scaling of the gain factor (represented by the letter “a” illustrated in FIG. 5A) in H(z) to limit the OTA output signal excursion, in contrast to the conventional delta-sigma modulator, thereby resulting in a smaller capacitor spread in the SC implementation of the analog-to-digital converter (ADC) of various embodiments. Furthermore, the use of a multi-bit ADC reduces the total capacitor areas that may be required.
(4) As the input to H(z) only contains the quantization error E(z), a much larger input X(z) approaching the reference full scale may be applied without causing nonlinearity and overloading of the analog-to-digital converter (ADC) or modulator. In contrast, a conventional delta-sigma modulator has to either limit the input to below −3 dBFS (i.e. −3 dB with respect to the full scale reference level) or even lower, especially for higher order modulator or use a smaller reference level which results in a lower dynamic range (DR) when the noise floor is fixed. The analog-to-digital converter (ADC) of various embodiments may accept an input closer to full scale, which translates to better DR performances.
(5) The compensator G(z) may implemented together with the summer and the ADC (e.g. the first combiner and the quantizer), thereby requiring a smaller capacitor area.
(6) A 3-level inherently linear DAC may be employed, thereby improving the dynamic range (DR) by about 6 dB.
(7) Combining the features of a single double sampling OTA, an input feed-forward and a multi-bit ADC may yield an analog-to-digital converter (ADC) or a switched capacitor (SC) delta-sigma modulator of various embodiments that is area and power efficient.

Various embodiments may provide a feed-forward delta-sigma modulator or ADC with two-path G(z) (or may be multi-path), summer and ADC implementation. In addition, various embodiments may also provide a 3-level mismatch cancellation SC DAC for double sampling SC circuits.

Various embodiments of the analog-to-digital converter (ADC) or the double sampling delta-sigma modulator architectures are area and power efficient, and may be used or adapted for a wide range of applications requiring analog-to-digital conversions, for example instrumentation, biomedical, wired and wireless applications.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. An analog-to-digital converter comprising:
an input configured to receive an input signal;
a feed-forward path connected to the input configured to feed forward the input signal;
a processing path comprising a loop filter, wherein the loop filter comprises at least one local feedback path configured to feed back an output signal of the loop filter to an input of the loop filter;
a first combiner configured to combine the input signal fed forward by the feed-forward path with an output of the processing path;
a quantizer configured to generate an output signal of the converter;
a feed-back path configured to feed back the output signal; and
a second combiner wherein the processing path is connected to the second combiner and the second combiner is configured to combine the input signal with the fed back output signal of the converter and supply the result of the combination to the processing path.

2. The analog-to-digital converter according to claim 1, wherein the loop filter comprises a first local feedback path configured to feed back an output of the loop filter to an input of the loop filter and a second local feedback path configured to feed back a delayed output of the loop filter to an input of the loop filter.

3. The analog-to-digital converter according to claim 1, wherein the loop filter further comprises a loop filter combiner configured to combine an input signal of the loop filter with the fed back output signal of the loop filter.

4. The analog-to-digital converter according to claim 1, wherein the loop filter comprises an integrator and the loop filter combiner is configured to supply the result of the combination to the integrator.

5. The analog-to-digital converter according to claim 4, wherein the integrator is configured to generate the output signal of the loop filter.

6. The analog-to-digital converter according to claim 1, wherein the first combiner is a multi-path combiner.

7. The analog-to-digital converter according to claim 6, wherein the first combiner comprises a first summer and a second summer and the quantizer includes a first comparator and a second comparator, wherein the output of the first summer is supplied to the first comparator and the output of the second summer is supplied to the second comparator.

8. The analog-to-digital converter according to claim 7, wherein the first summer and the first comparator are oppositely clocked with respect to the second summer and the second comparator.

9. The analog-to-digital converter according to claim 7, further comprising a multiplexer configured to multiplex the outputs of the first comparator and the second comparator.

10. The analog-to-digital converter according to claim 6, wherein the first combiner comprises two or more summers and the quantizer includes two or more comparators, wherein each summer is associated with a comparator and wherein the output of the summer is supplied to the comparator associated with the summer.

11. The analog-to-digital converter according to claim 10, further comprising a multiplexer configured to multiplex the outputs of the two or more comparators.

12. The analog-to-digital converter according to claim 1, wherein the feedback path comprises a switched-capacitor digital-to-analog converter.

13. The analog-to-digital converter according to claim 12, wherein the switched-capacitor digital-to-analog converter is supplied with a three-level signal and the switched-capacitor digital-to-analog converter comprises three switches, wherein each switch is associated with one level of the three-level signal and the switch is switched on if the three-level signal has the level associated with the switch.

14. The analog-to-digital converter according to claim 1, wherein the processing path further comprises a compensator configured to receive the output signal of the loop filter, and further configured to supply the output signal of the loop filter and a delayed output signal of the loop filter as the output of the processing path.
